(19) United States
(12) Patent Application Publication
(10) Pub. No.: US 2025/0070689 A1
(43) Pub. Date: Feb. 27, 2025

(54) MAXIMIZING PIEZOELECTRIC POWER GENERATION USING ACOUSTIC RESONANCE

(71) Applicant: International Business Machines Corporation, Armonk, NY (US)

(72) Inventors: Sarbajit K. Rakshit, Kolkata (IN); Jagabondhu Hazra, Bangalore (IN); Manikandan Padmanaban, Chennai (IN)

(73) Assignee: International Business Machines Corporation, Armonk, NY (US)

(21) Appl. No.: 18/238,010

(22) Filed: Aug. 25, 2023

(51) Int. Cl. H02N 2/18; H10N 30/30

(52) U.S. Cl. CPC H02N 2/188; H10N 30/30

(57) ABSTRACT

An embodiment adjusts a position of a piezoelectric generator within a hollow cylindrical tube, the position adjusted to cause the tube to vibrate at a first resonant frequency in response to an acoustic stimulus, the piezoelectric generator configured to close one end of the tube, the tube further comprising an open end disposed at an opposite end of the tube from the piezoelectric generator. An embodiment adjusts, by applying a voltage to the piezoelectric generator, a resonant frequency of the piezoelectric generator, the adjusting changing the resonant frequency of the piezoelectric generator to the first resonant frequency.

### BACKGROUND

The present invention relates generally to controlling an electric power generation configuration. More particularly, the present invention relates to a method, system, and computer program for maximizing piezoelectric power generation using acoustic resonance.

The piezoelectric effect is the ability of certain materials to generate an electric charge in response to applied mechanical stress. Piezoelectric power generation is the use of the piezoelectric effect to generate electricity from the kinetic energy produced by motions and other applied mechanical stresses. One source of vibrations applied to a piezoelectric power generator is the acoustic energy of sounds in an environment. Thus, a piezoelectric power generation apparatus installed in a known-noisy environment-such as an urban subway system, busy highway, or airport with frequent takeoffs and landings-generates electricity locally, without the need to burn fossil fuels or transport wind-or solar-generated electricity from another power generation location.

Resonance describes the phenomenon of increased amplitude that occurs when the frequency of an applied periodic force is equal or close to a natural frequency of the system on which the force acts. When an oscillating force is applied at a resonant frequency of a dynamic system, the system will oscillate at a higher amplitude than when the same force is applied at other, non-resonant frequencies. Frequencies at which the response amplitude is a relative maximum are also known as resonant frequencies or resonance frequencies of the system. Acoustic resonance is a phenomenon in which an acoustic system amplifies a sound wave with a frequency matching one of the acoustic system's own resonance frequencies. Because sound can occur at frequencies outside the range of human hearing, acoustic resonance can also occur at frequencies outside the range of human hearing. Any cylinder resonates at multiple frequencies, producing multiple musical pitches. The lowest frequency is called the fundamental frequency or the first harmonic. One example of an acoustic system is a cylinder or tube open to surrounding air at one end and closed at the other end. Sound impacting such a cylinder causes a standing wave to form inside the cylinder, with a wavelength dependent on the length of the cylinder. The cylinder's resonant frequency is the speed of sound in air divided by the wavelength of the standing wave.

### SUMMARY

The illustrative embodiments provide for maximizing piezoelectric power generation using acoustic resonance. An embodiment includes adjusting a position of a piezoelectric generator within a hollow cylindrical tube, the position adjusted to cause the tube to vibrate at a first resonant frequency in response to an acoustic stimulus, the piezoelectric generator configured to close one end of the tube, the tube further comprising an open end disposed at an opposite end of the tube from the piezoelectric generator. An embodiment includes adjusting, by applying a voltage to the piezoelectric generator, a resonant frequency of the piezoelectric generator, the adjusting changing the resonant frequency of the piezoelectric generator to the first resonant frequency. Other embodiments of this aspect include corresponding computer systems, apparatus, and computer programs recorded on one or more computer storage devices, each configured to perform the actions of the embodiment.

An embodiment includes a computer usable program product. The computer usable program product includes a computer-readable storage medium, and program instructions stored on the storage medium.

An embodiment includes a computer system. The computer system includes a processor, a computer-readable memory, and a computer-readable storage medium, and program instructions stored on the storage medium for execution by the processor via the memory.

### BRIEF DESCRIPTION OF THE DRAWINGS

The novel features believed characteristic of the invention are set forth in the appended claims. The invention itself, however, as well as a preferred mode of use, further objectives, and advantages thereof, will best be understood by reference to the following detailed description of the illustrative embodiments when read in conjunction with the accompanying drawings, wherein:

FIG. 1 depicts a block diagram of a computing environment in accordance with an illustrative embodiment;

FIG. 2 depicts a flowchart of an example process for loading of process software in accordance with an illustrative embodiment;

FIG. 3 depicts a block diagram of an example configuration for maximizing piezoelectric power generation using acoustic resonance in accordance with an illustrative embodiment;

FIG. 4 depicts an example of acoustic resonance in accordance with an illustrative embodiment;

FIG. 5 depicts an example of maximizing piezoelectric power generation using acoustic resonance in accordance with an illustrative embodiment; and

FIG. 6 depicts a flowchart of an example process for maximizing piezoelectric power generation using acoustic resonance in accordance with an illustrative embodiment.

### DETAILED DESCRIPTION

The illustrative embodiments recognize that, while piezoelectric power generators are usable to generate electricity from ambient sounds, even in an environment known to be noisy the generated sound pressure is unlikely to be sufficient to justify the cost of installing piezoelectric power generators. For example, if the average noise level in an urban subway system is around 114 decibels (dB), this produces a power intensity of approximately 0.25 Watts/meters squared (W/m²), necessitating four meters squared of piezoelectric power generators to generate one Watt of electricity. Thus, the illustrative embodiments recognize that there is a need to improve piezoelectric power generation, by making use of acoustic resonance.

The present disclosure addresses the deficiencies described above by providing a process (as well as a system, method, machine-readable medium, etc.) that adjusts a position of a piezoelectric generator within a hollow cylindrical tube to cause the tube to vibrate at a first resonant frequency in response to an acoustic stimulus, and adjusts, by applying a voltage to the piezoelectric generator, a resonant frequency of the piezoelectric generator to the first resonant frequency. Thus, the illustrative embodiments provide for maximizing piezoelectric power generation using acoustic resonance. For example, if a base noise level is 114 dB, using acoustic resonance can increase the noise level to 134 dB, producing a power intensity of 25 W/m² instead of the original 0.25 W/m².

An illustrative embodiment receives data of a designated power generation site at which an apparatus used by an embodiment to generate electricity is to be installed. Data of a designated power generation site includes an area of the site, measured or expected noise levels at the site and how frequently those noise levels are expected to occur, and measured or expected air temperatures at the site during a time at which electricity is expected to be generated at the site. For example, data of one designated power generation site, a tunnel in an urban subway system, might indicate that the site measures 500 meters by 2 meters (i.e., an area of 1000 square meters (m²)), that one hundred subway trains per day pass through the tunnel, each generating approximately 70 decibels (dB) for 30 seconds as they pass, and that because the tunnel is underground air temperatures in the tunnel range from 10 to 35 degrees Celsius all year.

An illustrative embodiment also receives data of materials to be used at the designated power generation site. Data of the materials to be used includes acoustic resonance data of a set of hollow cylindrical tubes to be installed at the designed power generation site. Acoustic resonance data includes data of the resonant frequencies of an example tube of a specified radius, closed at one end and open at the other end, at a particular air temperature. Data of the materials to be used also includes power generation data of a piezoelectric generator material to be disposed within each of the hollow cylindrical tubes, such as a resonant frequency range of the piezoelectric generator material, instructions for controlling a resonant frequency of the piezoelectric generator material is controlled within the material's resonant frequency range, and the material's electricity generation rate in response to acoustic stimuli.

The speed of sound in air (denoted by v_{T}) is (331.5+0.606T) meters per second (m/s), where T denotes a current air temperature in degrees Celsius. A hollow cylindrical tube closed at one end and open at an opposite end of the tube from the closed end has a tube length denoted by L. An acoustic resonance condition, in which there is a standing wave in the tube between a node point (at the closed end) and the open end, can only be satisfied when the length of the tube L=¼ (2n+1)λ, where n is a positive integer and λ denotes a wavelength of the standing wave in the tube. As the hollow cylindrical tube's resonant frequency is the speed of sound in air divided by the wavelength of the standing wave, the tube vibrates at a resonant frequency when the length of the tube L=¼ (2n+1) v_{T}/f, where f denotes a resonant frequency of the tube. Thus, if the current air temperature (and thus the speed of sound in the air) and the resonant frequency of a hollow cylindrical tube are known, and n is set to a known value, adjusting the tube to corresponding length L allows the tube to resonate when stimulated by an acoustic stimulus.

In a validation phase, an embodiment calculates an operational tube length range for a set of hollow cylindrical tubes to be installed at the designed power generation site. An operational tube length range is the range between tube lengths at which a tube will resonate when stimulated by an acoustic stimulus, at air temperatures between the minimum and maximum air temperatures expected at a site during a time at which electricity is expected to be generated at the site. For example, if the tube has a resonant frequency of 500 Hertz (Hz) and n is set to 1, using the tube length expression described herein the operational tube length range might be 0.50 m (at 10 degrees C.) to 0.53 m (at 35 degrees C.). If the operational tube length range is incompatible with the parameters of the designated power generation site (e.g., the operational tube length range is too long to fit within the site or is too expensive), an embodiment selects a smaller value for n (if possible), or alerts a user to select a different tube material with a higher resonant frequency (and thus a shorter operational tube length range) or a lower cost for the original operational tube length range, or alerts a user to select a different site in which the original operational tube length range will fit. If a tube material with a higher resonant frequency or a different power generation site is selected, an embodiment repeats the operational tube length range calculation and notification (if necessary) using data of the new tube material or power generation site in a manner described herein.

An embodiment manages a power generation site which is configured to include a set of hollow cylindrical tubes, each long enough to accommodate the calculated operational tube length range. Each tube has a piezoelectric generator configured to close one end of the tube. Each tube also includes an open end disposed at an opposite end of the tube from the piezoelectric generator. A position of the piezoelectric generator is adjustable, using an embodiment, within the tube, thus altering a length of the tube. When the tube length is correct, the tube will vibrate at a resonant frequency in response to an acoustic stimulus. The piezoelectric generator includes a material that generates electricity when stimulated by the tube's vibration. A resonant frequency of the piezoelectric generator is also adjustable, for example by applying a direct current voltage to the piezoelectric generator. Each tube also includes control circuitry an embodiment uses to adjust a position of a piezoelectric generator within a tube and adjust a resonant frequency of a piezoelectric generator. Each tube also includes circuitry conducting electricity generated by a piezoelectric generator to a power grid, storage battery, or another configuration that uses electricity generated at the power generation site.

An embodiment receives meteorological data, including a measurement of a current air temperature at a tube of the power generation site or a forecast of an air temperature in a region including a tube of the power generation site. In one embodiment, meteorological data also includes one or more of a current or forecast measurement of humidity, air pressure, and wind. An embodiment uses the meteorological data to adjust a position of a piezoelectric generator within a tube, causing the tube to vibrate at a first resonant frequency in response to an acoustic stimulus. One embodiment adjusts a position of a piezoelectric generator to the length required to satisfy the expression L=¼ (2n+1) v_{T}/f, where v_{T} denotes the speed of sound in air, n is a predefined positive integer, and f is an assumed or measured resonant frequency of the tube. If a current or forecast measurement of humidity, air pressure, and wind is available, an embodiment uses this data in calculating the speed of sound in air. Another embodiment uses test data including previous acoustic stimuli and corresponding tube vibrations, at various tube lengths and air temperatures, to obtain data correlating an air temperature to a tube length at which a tube vibrates at a resonant frequency. The embodiment uses the data to adjust a position of a piezoelectric generator to the length corresponding to a current air temperature. Another embodiment uses test data including previous acoustic stimuli and corresponding electricity generation rates, at various tube lengths and air temperatures, to obtain data correlating an air temperature to a tube length at which maximum power is generated (because the tube is vibrating at a resonant frequency). The embodiment uses the data to adjust a position of a piezoelectric generator to the length corresponding to a current air temperature. Another embodiment uses test data including previous acoustic stimuli and corresponding tube vibrations or electrical power generation rates, at various tube lengths and air temperatures, to obtain data correlating an air temperature and a specific type of acoustic stimulus to a tube length at which a tube vibrates at a resonant frequency. The embodiment uses the data to adjust a position of a piezoelectric generator to the length corresponding to a current air temperature and the specific type of acoustic stimulus that is expected next. For example, cargo trains are often both heavier and longer than passenger trains. Thus, at a power generation site adjacent to a railroad track used by both passenger and cargo trains, an embodiment might the data to adjust a position of a piezoelectric generator to the length corresponding to a current air temperature and the type of train that is expected next. Another embodiment uses test data including previous acoustic stimuli and corresponding tube vibrations or power generation rates, at various tube lengths and air temperatures, to train a neural network model to predict a tube length at which a tube vibrates at a resonant frequency or at which power generation from the piezoelectric generator within the tube is at a maximum, given a specific set of input conditions. The embodiment then uses current input conditions (e.g., the current air temperature, the type of stimulus expected next) and the trained neural network to adjust a position of a piezoelectric generator to the length predicted by the trained neural network.

One embodiment monitors a current air temperature at a tube of the power generation site, and when the air temperature has changed by more than a threshold amount, the embodiment adjusts a position of a piezoelectric generator within a tube in a manner described herein. Another embodiment uses an air temperature forecast, for a region including a tube of the power generation site, to adjust a position of a piezoelectric generator within a tube in a manner described herein at a time when the air temperature is forecast to change by more than a threshold amount. For example, if the air temperature is predicted to drop 20 degrees Celsius between noon and 1 pm (as can happen due to a cold front), an embodiment might anticipate the forecast change by adjusting a position of a piezoelectric generator within a tube in a manner described herein just before noon, or by making several smaller adjustments over the noon to 1 pm period.

An embodiment also adjusts a resonant frequency of a piezoelectric generator within a tube at the power generation site by applying a voltage to the piezoelectric generator. One embodiment changes a resonant frequency of a piezoelectric generator to match an assumed or measured resonant frequency of the tube, at the tube's current length. Another embodiment changes a resonant frequency of a piezoelectric generator to a frequency at which electrical power generation from the piezoelectric generator is at a maximum, indicating that the piezoelectric generator's resonant frequency now matches that of the tube in which the piezoelectric generator is installed. One embodiment adjusts a resonant frequency of a piezoelectric generator whenever a position of a piezoelectric generator within a tube is adjusted in a manner described herein. Another embodiment adjusts a resonant frequency of a piezoelectric generator whenever a position of a piezoelectric generator within a tube changes by more than a threshold amount.

The piezoelectric generator generates electricity in response to an acoustic stimulus. Thus, when an embodiment has adjusted a position of a piezoelectric generator within a tube so that the tube vibrates at a resonant frequency in response to an acoustic stimulus, and has adjusted a resonant frequency of a piezoelectric generator within a tube to match an assumed or measured resonant frequency of the tube, at the tube's current length, the piezoelectric generator generates more electricity in response to an acoustic stimulus than would be the case without using resonance. For example, if the power generation site is a subway tunnel or adjacent to an airport runway, the piezoelectric generator generates electricity in response to a passing subway train or aircraft taking off from the runway.

For the sake of clarity of the description, and without implying any limitation thereto, the illustrative embodiments are described using some example configurations. From this disclosure, those of ordinary skill in the art will be able to conceive many alterations, adaptations, and modifications of a described configuration for achieving a described purpose, and the same are contemplated within the scope of the illustrative embodiments.

Furthermore, simplified diagrams of the data processing environments are used in the figures and the illustrative embodiments. In an actual computing environment, additional structures or components that are not shown or described herein, or structures or components different from those shown but for a similar function as described herein may be present without departing the scope of the illustrative embodiments.

Furthermore, the illustrative embodiments are described with respect to specific actual or hypothetical components only as examples. Any specific manifestations of these and other similar artifacts are not intended to be limiting to the invention. Any suitable manifestation of these and other similar artifacts can be selected within the scope of the illustrative embodiments.

The examples in this disclosure are used only for the clarity of the description and are not limiting to the illustrative embodiments. Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed above.

Furthermore, the illustrative embodiments may be implemented with respect to any type of data, data source, or access to a data source over a data network. Any type of data storage device may provide the data to an embodiment of the invention, either locally at a data processing system or over a data network, within the scope of the invention. Where an embodiment is described using a mobile device, any type of data storage device suitable for use with the mobile device may provide the data to such embodiment, either locally at the mobile device or over a data network, within the scope of the illustrative embodiments.

The illustrative embodiments are described using specific code, computer readable storage media, high-level features, designs, architectures, protocols, layouts, schematics, and tools only as examples and are not limiting to the illustrative embodiments. Furthermore, the illustrative embodiments are described in some instances using particular software, tools, and data processing environments only as an example for the clarity of the description. The illustrative embodiments may be used in conjunction with other comparable or similarly purposed structures, systems, applications, or architectures. For example, other comparable mobile devices, structures, systems, applications, or architectures therefor, may be used in conjunction with such embodiment of the invention within the scope of the invention. An illustrative embodiment may be implemented in hardware, software, or a combination thereof.

The examples in this disclosure are used only for the clarity of the description and are not limiting to the illustrative embodiments. Additional data, operations, actions, tasks, activities, and manipulations will be conceivable from this disclosure and the same are contemplated within the scope of the illustrative embodiments.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

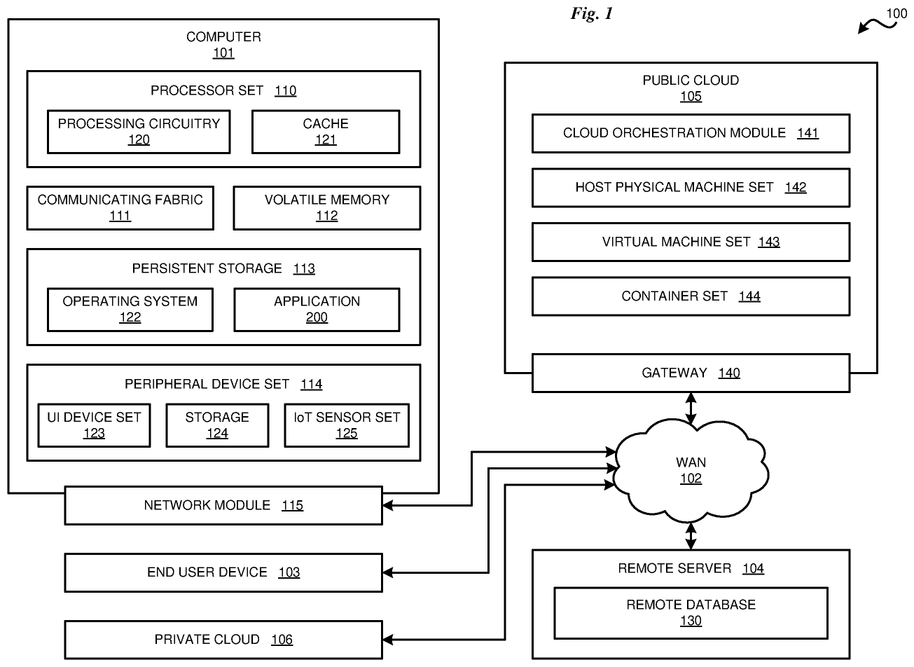

With reference to FIG. 1, this figure depicts a block diagram of a computing environment 100. Computing environment 100 contains an example of an environment for the execution of at least some of the computer code involved in performing the inventive methods, such as a power generation control application 200 that maximizes piezoelectric power generation using acoustic resonance. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Measured service: cloud systems automatically control and optimize resource use by leveraging a metering capability at some level of abstraction appropriate to the type of service (e.g., storage, processing, bandwidth, and active user accounts). Resource usage can be monitored, controlled, reported, and invoiced, providing transparency for both the provider and consumer of the utilized service.

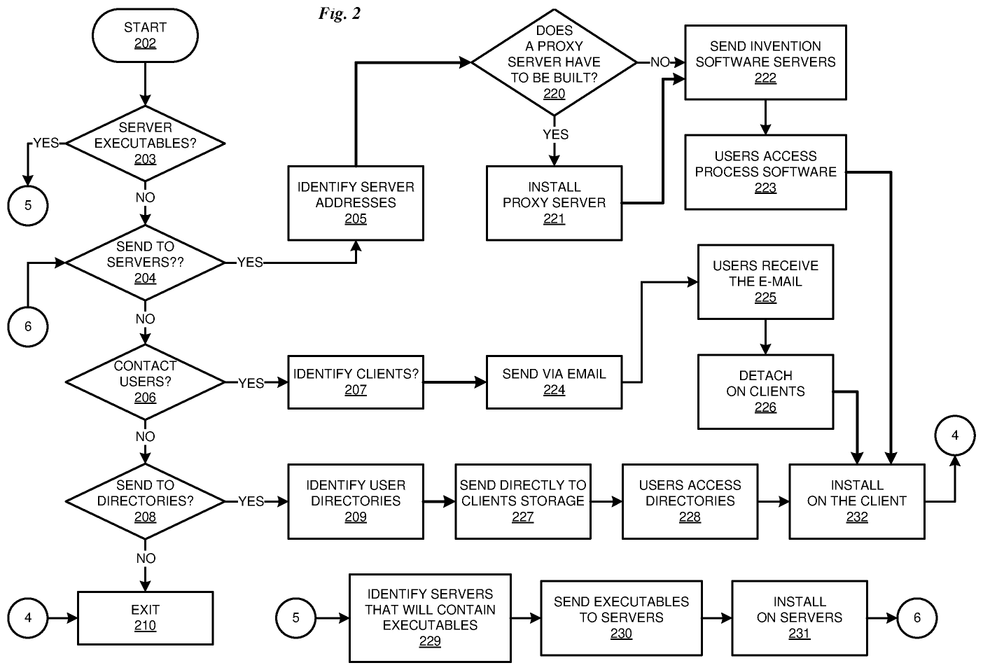

With reference to FIG. 2, this figure depicts a flowchart of an example process for loading of process software in accordance with an illustrative embodiment. The flowchart can be executed by a device such as computer 101, end user device 103, remote server 104, or a device in private cloud 106 or public cloud 105 in FIG. 1.

While it is understood that the process software implementing maximizing piezoelectric power generation using acoustic resonance may be deployed by manually loading it directly in the client, server, and proxy computers via loading a storage medium such as a CD, DVD, etc., the process software may also be automatically or semi-automatically deployed into a computer system by sending the process software to a central server or a group of central servers. The process software is then downloaded into the client computers that will execute the process software. Alternatively, the process software is sent directly to the client system via e-mail. The process software is then either detached to a directory or loaded into a directory by executing a set of program instructions that detaches the process software into a directory. Another alternative is to send the process software directly to a directory on the client computer hard drive. When there are proxy servers, the process will select the proxy server code, determine on which computers to place the proxy servers' code, transmit the proxy server code, and then install the proxy server code on the proxy computer. The process software will be transmitted to the proxy server, and then it will be stored on the proxy server.

Step 202 begins the deployment of the process software. An initial step is to determine if there are any programs that will reside on a server or servers when the process software is executed (203). If this is the case, then the servers that will contain the executables are identified (229). The process software for the server or servers is transferred directly to the servers' storage via FTP or some other protocol or by copying though the use of a shared file system (230). The process software is then installed on the servers (231).

Next, a determination is made on whether the process software is to be deployed by having users access the process software on a server or servers (204). If the users are to access the process software on servers, then the server addresses that will store the process software are identified (205).

A determination is made if a proxy server is to be built (220) to store the process software. A proxy server is a server that sits between a client application, such as a Web browser, and a real server. It intercepts all requests to the real server to see if it can fulfill the requests itself. If not, it forwards the request to the real server. The two primary benefits of a proxy server are to improve performance and to filter requests. If a proxy server is required, then the proxy server is installed (221). The process software is sent to the (one or more) servers either via a protocol such as FTP, or it is copied directly from the source files to the server files via file sharing (222). Another embodiment involves sending a transaction to the (one or more) servers that contained the process software, and have the server process the transaction and then receive and copy the process software to the server's file system. Once the process software is stored at the servers, the users via their client computers then access the process software on the servers and copy to their client computers file systems (223). Another embodiment is to have the servers automatically copy the process software to each client and then run the installation program for the process software at each client computer. The user executes the program that installs the process software on his client computer (232) and then exits the process (210).

In step 206 a determination is made whether the process software is to be deployed by sending the process software to users via e-mail. The set of users where the process software will be deployed are identified together with the addresses of the user client computers (207). The process software is sent via e-mail to each of the users' client computers (224). The users then receive the e-mail (225) and then detach the process software from the e-mail to a directory on their client computers (226). The user executes the program that installs the process software on his client computer (232) and then exits the process (210).

Lastly, a determination is made on whether the process software will be sent directly to user directories on their client computers (208). If so, the user directories are identified (209). The process software is transferred directly to the user's client computer directory (227). This can be done in several ways such as, but not limited to, sharing the file system directories and then copying from the sender's file system to the recipient user's file system or, alternatively, using a transfer protocol such as File Transfer Protocol (FTP). The users access the directories on their client file systems in preparation for installing the process software (228). The user executes the program that installs the process software on his client computer (232) and then exits the process (210).

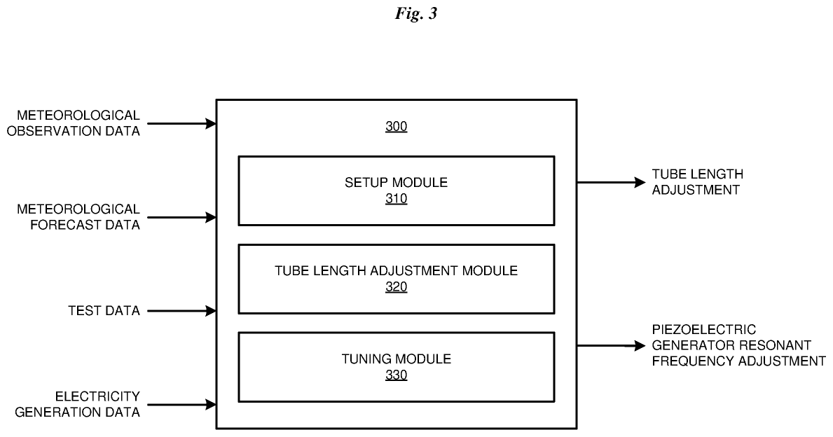

With reference to FIG. 3, this figure depicts a block diagram of an example configuration for maximizing piezoelectric power generation using acoustic resonance in accordance with an illustrative embodiment. Application 300 is the same as application 200 in FIG. 1.

In the illustrated embodiment, application 300 receives data of a designated power generation site at which an apparatus used by an embodiment to generate electricity is to be installed. Data of a designated power generation site includes an area of the site, measured or expected noise levels at the site and how frequently those noise levels are expected to occur, and measured or expected air temperatures at the site during a time at which electricity is expected to be generated at the site. For example, data of one designated power generation site, a tunnel in an urban subway system, might indicate that the site measures 500 meters by 2 meters (i.e., an area of 1000 square meters (m²)), that one hundred subway trains per day pass through the tunnel, each generating approximately 70 decibels (dB) for 30 seconds as they pass, and that because the tunnel is underground air temperatures in the tunnel range from 10 to 35 degrees Celsius all year.

Application 300 also receives data of materials to be used at the designated power generation site. Data of the materials to be used includes acoustic resonance data of a set of hollow cylindrical tubes to be installed at the designed power generation site. Acoustic resonance data includes data of the resonant frequencies of an example tube of a specified radius, closed at one end and open at the other end, at a particular air temperature. Data of the materials to be used also includes power generation data of a piezoelectric generator material to be disposed within each of the hollow cylindrical tubes, such as a resonant frequency range of the piezoelectric generator material, instructions for controlling a resonant frequency of the piezoelectric generator material is controlled within the material's resonant frequency range, and the material's electricity generation rate in response to acoustic stimuli.

Setup module 310 calculates an operational tube length range for a set of hollow cylindrical tubes to be installed at the designed power generation site. An operational tube length range is the range between tube lengths at which a tube will resonate when stimulated by an acoustic stimulus, at air temperatures between the minimum and maximum air temperatures expected at a site during a time at which electricity is expected to be generated at the site. For example, if the tube has a resonant frequency of 500 Hertz (Hz) and n is set to 1, using the tube length expression described herein the operational tube length range might be 0.50 m (at 10 degrees C.) to 0.53 m (at 35 degrees C.). If the operational tube length range is incompatible with the parameters of the designated power generation site (e.g., the operational tube length range is too long to fit within the site or is too expensive), module 310 selects a smaller value for n (if possible), or alerts a user to select a different tube material with a higher resonant frequency (and thus a shorter operational tube length range) or a lower cost for the original operational tube length range, or alerts a user to select a different site in which the original operational tube length range will fit. If a tube material with a higher resonant frequency or a different power generation site is selected, module 310 repeats the operational tube length range calculation and notification (if necessary) using data of the new tube material or power generation site in a manner described herein.

Application 300 manages a designated power generation site which is configured to include a set of hollow cylindrical tubes, each long enough to accommodate the calculated operational tube length range. Each tube has a piezoelectric generator configured to close one end of the tube. Each tube also includes an open end disposed at an opposite end of the tube from the piezoelectric generator. A position of the piezoelectric generator is adjustable, using an embodiment, within the tube, thus altering a length of the tube. When the tube length is correct, the tube will vibrate at a resonant frequency in response to an acoustic stimulus. The piezoelectric generator includes a material that generates electricity when stimulated by the tube's vibration. A resonant frequency of the piezoelectric generator is also adjustable, for example by applying a direct current voltage to the piezoelectric generator. Each tube also includes control circuitry an embodiment uses to adjust a position of a piezoelectric generator within a tube and adjust a resonant frequency of a piezoelectric generator. Each tube also includes circuitry conducting electricity generated by a piezoelectric generator to a power grid, storage battery, or another configuration that uses electricity generated at the power generation site.

Application 300 receives meteorological data, including a measurement of a current air temperature at a tube of the power generation site or a forecast of an air temperature in a region including a tube of the power generation site. In one implementation of application 300, meteorological data also includes one or more of a current or forecast measurement of humidity, air pressure, and wind. Tube length adjustment module 320 uses the meteorological data to adjust a position of a piezoelectric generator within a tube, causing the tube to vibrate at a first resonant frequency in response to an acoustic stimulus. One implementation of module 320 adjusts a position of a piezoelectric generator to the length required to satisfy the expression L=¼ (2n+1) v_{T}/f, where v_{T} denotes the speed of sound in air, n is a predefined positive integer, and f is an assumed or measured resonant frequency of the tube. If a current or forecast measurement of humidity, air pressure, and wind is available, an implementation of module 320 uses this data in calculating the speed of sound in air. Another implementation of module 320 uses test data including previous acoustic stimuli and corresponding tube vibrations, at various tube lengths and air temperatures, to obtain data correlating an air temperature to a tube length at which a tube vibrates at a resonant frequency. The implementation uses the data to adjust a position of a piezoelectric generator to the length corresponding to a current air temperature. Another implementation of module 320 uses test data including previous acoustic stimuli and corresponding electricity generation rates, at various tube lengths and air temperatures, to obtain data correlating an air temperature to a tube length at which maximum power is generated (because the tube is vibrating at a resonant frequency). The implementation uses the data to adjust a position of a piezoelectric generator to the length corresponding to a current air temperature. Another implementation of module 320 uses test data including previous acoustic stimuli and corresponding tube vibrations or electrical power generation rates, at various tube lengths and air temperatures, to obtain data correlating an air temperature and a specific type of acoustic stimulus to a tube length at which a tube vibrates at a resonant frequency. The implementation uses the data to adjust a position of a piezoelectric generator to the length corresponding to a current air temperature and the specific type of acoustic stimulus that is expected next. For example, cargo trains are often both heavier and longer than passenger trains. Thus, at a power generation site adjacent to a railroad track used by both passenger and cargo trains, module 320 might the data to adjust a position of a piezoelectric generator to the length corresponding to a current air temperature and the type of train that is expected next. Another implementation of module 320 uses test data including previous acoustic stimuli and corresponding tube vibrations or power generation rates, at various tube lengths and air temperatures, to train a neural network model to predict a tube length at which a tube vibrates at a resonant frequency or at which power generation from the piezoelectric generator within the tube is at a maximum, given a specific set of input conditions. The implementation then uses current input conditions (e.g., the current air temperature, the type of stimulus expected next) and the trained neural network to adjust a position of a piezoelectric generator to the length predicted by the trained neural network.

One implementation of module 320 monitors a current air temperature at a tube of the power generation site, and when the air temperature has changed by more than a threshold amount, module 320 adjusts a position of a piezoelectric generator within a tube in a manner described herein. Another implementation of module 320 uses an air temperature forecast, for a region including a tube of the power generation site, to adjust a position of a piezoelectric generator within a tube in a manner described herein at a time when the air temperature is forecast to change by more than a threshold amount. For example, if the air temperature is predicted to drop 20 degrees Celsius between noon and 1 pm (as can happen due to a cold front), module 320 might anticipate the forecast change by adjusting a position of a piezoelectric generator within a tube in a manner described herein just before noon, or by making several smaller adjustments over the noon to 1 pm period.

Tuning module 330 also adjusts a resonant frequency of a piezoelectric generator within a tube at the power generation site by applying a voltage to the piezoelectric generator. One implementation of module 330 changes a resonant frequency of a piezoelectric generator to match an assumed or measured resonant frequency of the tube, at the tube's current length. Another implementation of module 330 changes a resonant frequency of a piezoelectric generator to a frequency at which electrical power generation from the piezoelectric generator is at a maximum, indicating that the piezoelectric generator's resonant frequency now matches that of the tube in which the piezoelectric generator is installed. One implementation of module 330 adjusts a resonant frequency of a piezoelectric generator whenever a position of a piezoelectric generator within a tube is adjusted in a manner described herein. Another implementation of module 330 adjusts a resonant frequency of a piezoelectric generator whenever a position of a piezoelectric generator within a tube changes by more than a threshold amount.

The piezoelectric generator generates electricity in response to an acoustic stimulus. Thus, when application 300 has adjusted a position of a piezoelectric generator within a tube so that the tube vibrates at a resonant frequency in response to an acoustic stimulus, and has adjusted a resonant frequency of a piezoelectric generator within a tube to match an assumed or measured resonant frequency of the tube, at the tube's current length, the piezoelectric generator generates more electricity in response to an acoustic stimulus than would be the case without using resonance. For example, if the power generation site is a subway tunnel or adjacent to an airport runway, the piezoelectric generator generates electricity in response to a passing subway train or aircraft taking off from the runway.

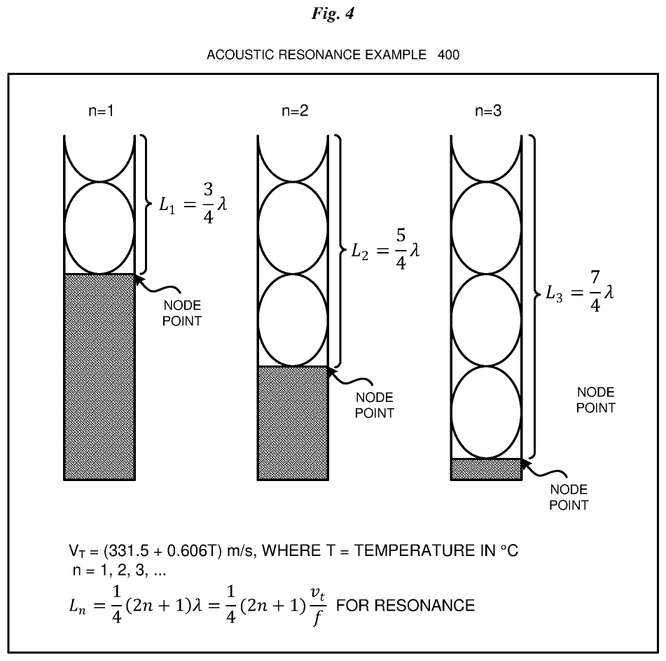

With reference to FIG. 4, this figure depicts an example of acoustic resonance in accordance with an illustrative embodiment. In particular, acoustic resonance example 400 depicts acoustic resonance within a hollow cylindrical tube closed at one end and open at an opposite end of the tube from the closed end. An acoustic resonance condition, in which there is a standing wave in the tube between a node point (at the closed end) and the open end, can only be satisfied when the length of the tube L=¼ (2n+1)λ, where n is a positive integer and λ denotes a wavelength of the standing wave in the tube. As the hollow cylindrical tube's resonant frequency is the speed of sound in air divided by the wavelength of the standing wave, the tube vibrates at a resonant frequency when the length of the tube L=¼ (2n+1) v_{T}/f, where f denotes a resonant frequency of the tube.

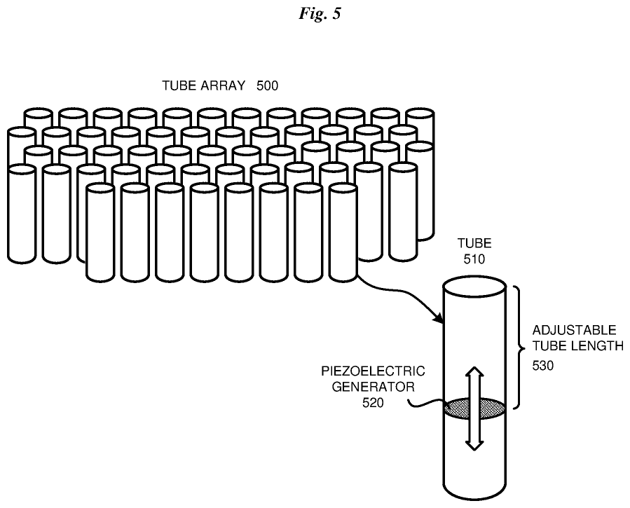

With reference to FIG. 5, this figure depicts an example of maximizing piezoelectric power generation using acoustic resonance in accordance with an illustrative embodiment. The example can be executed using application 300 in FIG. 3.

As depicted, tube array 500 is installed in a power generation site. Tube array 500 a set of hollow cylindrical tubes, each long enough to accommodate the calculated operational tube length range. Each tube (e.g., tube 510) has a piezoelectric generator (e.g., piezoelectric generator 520) configured to close one end of the tube. Each tube also includes an open end disposed at an opposite end of the tube from the piezoelectric generator. A position of the piezoelectric generator is adjustable, generating adjustable tube length 530. When adjustable tube length 530 is correct, tube 510 will vibrate at a resonant frequency in response to an acoustic stimulus. Piezoelectric generator 520 includes a material that generates electricity when stimulated by tube 510's vibration. A resonant frequency of piezoelectric generator 520 is also adjustable, for example by applying a direct current voltage to piezoelectric generator 520. Each tube also includes control circuitry (not shown) usable to adjust a position of a piezoelectric generator within a tube and adjust a resonant frequency of a piezoelectric generator, and circuitry conducting electricity generated by piezoelectric generator 520 to a power grid, storage battery, or another configuration that uses electricity generated at the power generation site.

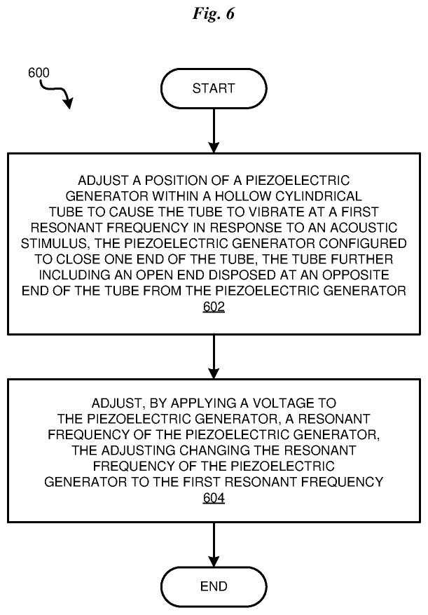

With reference to FIG. 6, this figure depicts a flowchart of an example process for maximizing piezoelectric power generation using acoustic resonance in accordance with an illustrative embodiment. Process 600 can be implemented in application 200 in FIG. 3.

In the illustrated embodiment, at block 602, the process adjusts a position of a piezoelectric generator within a hollow cylindrical tube to cause the tube to vibrate at a first resonant frequency in response to an acoustic stimulus, the piezoelectric generator configured to close one end of the tube, the tube further including an open end disposed at an opposite end of the tube from the piezoelectric generator. At block 604, the process adjusts, by applying a voltage to the piezoelectric generator, a resonant frequency of the piezoelectric generator, the adjusting changing the resonant frequency of the piezoelectric generator to the first resonant frequency. Then the process ends.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “illustrative” is used herein to mean “serving as an example, instance or illustration.” Any embodiment or design described herein as “illustrative” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

Thus, a computer implemented method, system or apparatus, and computer program product are provided in the illustrative embodiments for managing participation in online communities and other related features, functions, or operations. Where an embodiment or a portion thereof is described with respect to a type of device, the computer implemented method, system or apparatus, the computer program product, or a portion thereof, are adapted or configured for use with a suitable and comparable manifestation of that type of device.

Where an embodiment is described as implemented in an application, the delivery of the application in a Software as a Service (Saas) model is contemplated within the scope of the illustrative embodiments. In a SaaS model, the capability of the application implementing an embodiment is provided to a user by executing the application in a cloud infrastructure. The user can access the application using a variety of client devices through a thin client interface such as a web browser (e.g., web-based e-mail), or other light-weight client-applications. The user does not manage or control the underlying cloud infrastructure including the network, servers, operating systems, or the storage of the cloud infrastructure. In some cases, the user may not even manage or control the capabilities of the SaaS application. In some other cases, the SaaS implementation of the application may permit a possible exception of limited user-specific application configuration settings.

Embodiments of the present invention may also be delivered as part of a service engagement with a client corporation, nonprofit organization, government entity, internal organizational structure, or the like. Aspects of these embodiments may include configuring a computer system to perform, and deploying software, hardware, and web services that implement, some or all of the methods described herein. Aspects of these embodiments may also include analyzing the client's operations, creating recommendations responsive to the analysis, building systems that implement portions of the recommendations, integrating the systems into existing processes and infrastructure, metering use of the systems, allocating expenses to users of the systems, and billing for use of the systems. Although the above embodiments of present invention each have been described by stating their individual advantages, respectively, present invention is not limited to a particular combination thereof. To the contrary, such embodiments may also be combined in any way and number according to the intended deployment of present invention without losing their beneficial effects.

What is claimed is:

1. A computer-implemented method comprising:
adjusting a position of a piezoelectric generator within a hollow cylindrical tube, the position adjusted to cause the tube to vibrate at a first resonant frequency in response to an acoustic stimulus, the piezoelectric generator configured to close one end of the tube, the tube further comprising an open end disposed at an opposite end of the tube from the piezoelectric generator; and
adjusting, by applying a voltage to the piezoelectric generator, a resonant frequency of the piezoelectric generator, the adjusting changing the resonant frequency of the piezoelectric generator to the first resonant frequency.

2. The computer-implemented method of claim 1, further comprising:
calculating, using an expected temperature range at a power generation site comprising the tube, an operational tube length range of the tube.

3. The computer-implemented method of claim 1, wherein adjusting the position of the piezoelectric generator is performed using a measurement of a current air temperature in a region comprising the tube.

4. The computer-implemented method of claim 1, wherein adjusting the position of the piezoelectric generator is performed using an air temperature forecast for a region comprising the tube.

5. The computer-implemented method of claim 1, wherein adjusting the position of the piezoelectric generator is performed using test data, the test data comprising a previous acoustic stimulus and a previous vibration of the tube in response to the previous acoustic stimulus.

6. The computer-implemented method of claim 1, wherein the piezoelectric generator generates electricity in response to a vibration of the tube.

7. A computer program product comprising one or more computer readable storage media, and program instructions collectively stored on the one or more computer readable storage media, the program instructions executable by a processor to cause the processor to perform operations comprising:
adjusting a position of a piezoelectric generator within a hollow cylindrical tube, the position adjusted to cause the tube to vibrate at a first resonant frequency in response to an acoustic stimulus, the piezoelectric generator configured to close one end of the tube, the tube further comprising an open end disposed at an opposite end of the tube from the piezoelectric generator; and
adjusting, by applying a voltage to the piezoelectric generator, a resonant frequency of the piezoelectric generator, the adjusting changing the resonant frequency of the piezoelectric generator to the first resonant frequency.

8. The computer program product of claim 7, wherein the stored program instructions are stored in a computer readable storage device in a data processing system, and wherein the stored program instructions are transferred over a network from a remote data processing system.

9. The computer program product of claim 7, wherein the stored program instructions are stored in a computer readable storage device in a server data processing system, and wherein the stored program instructions are downloaded in response to a request over a network to a remote data processing system for use in a computer readable storage device associated with the remote data processing system, further comprising:
program instructions to meter use of the program instructions associated with the request; and
program instructions to generate an invoice based on the metered use.

10. The computer program product of claim 7, further comprising:
calculating, using an expected temperature range at a power generation site comprising the tube, an operational tube length range of the tube.

11. The computer program product of claim 7, wherein adjusting the position of the piezoelectric generator is performed using a measurement of a current air temperature in a region comprising the tube.

12. The computer program product of claim 7, wherein adjusting the position of the piezoelectric generator is performed using an air temperature forecast for a region comprising the tube.

13. The computer program product of claim 7, wherein adjusting the position of the piezoelectric generator is performed using test data, the test data comprising a previous acoustic stimulus and a previous vibration of the tube in response to the previous acoustic stimulus.

14. The computer program product of claim 7, wherein the piezoelectric generator generates electricity in response to a vibration of the tube.

15. A computer system comprising a processor and one or more computer readable storage media, and program instructions collectively stored on the one or more computer readable storage media, the program instructions executable by the processor to cause the processor to perform operations comprising:
adjusting a position of a piezoelectric generator within a hollow cylindrical tube, the position adjusted to cause the tube to vibrate at a first resonant frequency in response to an acoustic stimulus, the piezoelectric generator configured to close one end of the tube, the tube further comprising an open end disposed at an opposite end of the tube from the piezoelectric generator; and
adjusting, by applying a voltage to the piezoelectric generator, a resonant frequency of the piezoelectric generator, the adjusting changing the resonant frequency of the piezoelectric generator to the first resonant frequency.

16. The computer system of claim 15, further comprising:
calculating, using an expected temperature range at a power generation site comprising the tube, an operational tube length range of the tube.

17. The computer system of claim 15, wherein adjusting the position of the piezoelectric generator is performed using a measurement of a current air temperature in a region comprising the tube.

18. The computer system of claim 15, wherein adjusting the position of the piezoelectric generator is performed using an air temperature forecast for a region comprising the tube.

19. The computer system of claim 15, wherein adjusting the position of the piezoelectric generator is performed using test data, the test data comprising a previous acoustic stimulus and a previous vibration of the tube in response to the previous acoustic stimulus.

20. The computer system of claim 15, wherein the piezoelectric generator generates electricity in response to a vibration of the tube.
